(19) United States
(12) Patent Application Publication
(10) Pub. No.: US 2025/0311259 A1
(43) Pub. Date: Oct. 2, 2025

(54) METHOD OF MANUFACTURING SEMICONDUCTOR DEVICE AND SEMICONDUCTOR DEVICE

(71) Applicant: Tokyo Electron Limited, Tokyo (JP)

(72) Inventors: Hajime NAKABAYASHI, Nirasaki-shi (JP); Takahiro YOSHIMATSU, Nirasaki-shi (JP)

(21) Appl. No.: 19/235,876

(22) Filed: Jun. 12, 2025

Related U.S. Application Data
(63) Continuation of application No. PCT/JP2023/043085, filed on Dec. 1, 2023.

(30) Foreign Application Priority Data
Dec. 15, 2022 (JP) 2022-200033

(51) Int. Cl. H10D 12/01; H01L 21/383; H10D 12/00; H10D 62/80; H10D 62/82

(52) U.S. Cl. CPC H10D 12/021; H01L 21/383; H10D 12/211; H10D 62/8271; H10D 62/875

(57) ABSTRACT

A method of manufacturing a semiconductor device including a tin oxide semiconductor having a pn junction between a source electrode and a drain electrode, the method including, changing a conductivity type of a portion of a layer made of the tin oxide semiconductor to form the pn junction.

### CROSS-REFERENCE TO RELATED APPLICATIONS

The application is a Bypass Continuation Application of PCT International Application No. PCT/JP2023/043085, filed on Dec. 1, 2023 and designating the United States, the international application being based upon and claiming the benefit of priority from Japanese Patent Application No. 2022-200033, filed on Dec. 15, 2022, the entire contents of which is incorporated herein by reference.

### TECHNICAL FIELD

The present disclosure relates to a method of manufacturing a semiconductor device and a semiconductor device.

### BACKGROUND

As a transistor capable of operating under the control of an extremely low voltage, a tunnel field-effect transistor (hereinafter, abbreviated as “TFET”) is known. The TFET performs switching by using quantum tunneling via a barrier, rather than by forming an inversion layer as a conventional MOSFET does. Specifically, the amount of electrons or positive holes tunneling through the barrier, is controlled by a gate voltage. In the TFET, a source composed of a p-type semiconductor layer and a channel composed of an n-type semiconductor layer are disposed in a heterojunction between a source electrode and a drain electrode (e.g., see Patent Document 1).

The p-type semiconductor layer is made of a Group IV semiconductor, includes silicon (Si) as a main component, and has a p-type conductivity by addition of an impurity. The n-type semiconductor layer is made of an oxide semiconductor, includes zinc oxide (ZnO) as a main component, and has an n-type conductivity by at least one of addition of an impurity or introduction of a defect.

### PRIOR ART DOCUMENTS

### Patent Documents

Patent Document 1: International Publication No. 2019/107411

### SUMMARY

According to one embodiment of the present disclosure, there is provided a method of manufacturing a semiconductor device including a tin oxide semiconductor having a pn junction between a source electrode and a drain electrode, the method including, changing a conductivity type of a portion of a layer made of the tin oxide semiconductor to form the pn junction.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating a structure of a TFET manufactured by a method of manufacturing a semiconductor device according to a first embodiment.

FIG. 2A is a diagram illustrating an energy band structure of a semiconductor layer of the TFET as an n-type transistor.

FIG. 2B is a diagram illustrating an energy band structure of the semiconductor layer of the TFET as an n-type transistor.

FIG. 3 is a diagram illustrating in detail an energy band structure of a p-type SnO layer and an n-type SnO₂ layer in the case of transistor on.

FIG. 4A is a process diagram illustrating a method of manufacturing the TFET as the method of manufacturing the semiconductor device according to the first embodiment.

FIG. 4B is a process diagram illustrating the method of manufacturing the TFET as the method of manufacturing the semiconductor device according to the first embodiment.

FIG. 4C is a process diagram illustrating the method of manufacturing the TFET as the method of manufacturing the semiconductor device according to the first embodiment.

FIG. 4D is a process diagram illustrating the method of manufacturing the TFET as the method of manufacturing the semiconductor device according to the first embodiment.

FIG. 4E is a process diagram illustrating the method of manufacturing the TFET as the method of manufacturing the semiconductor device according to the first embodiment.

FIG. 4F is a process diagram illustrating the method of manufacturing the TFET as the method of manufacturing the semiconductor device according to the first embodiment.

FIG. 4G is a process diagram illustrating the method of manufacturing the TFET as the method of manufacturing the semiconductor device according to the first embodiment.

FIG. 4H is a process diagram illustrating the method of manufacturing the TFET as the method of manufacturing the semiconductor device according to the first embodiment.

FIG. 4I is a process diagram illustrating the method of manufacturing the TFET as the method of manufacturing the semiconductor device according to the first embodiment.

FIG. 4J is a process diagram illustrating the method of manufacturing the TFET as the method of manufacturing the semiconductor device according to the first embodiment.

FIG. 5 is a cross-sectional view schematically illustrating a structure of a TFET manufactured by a method of manufacturing a semiconductor device according to a second embodiment.

FIG. 6A is a diagram illustrating an energy band structure of a semiconductor layer of the TFET as a p-type transistor.

FIG. 6B is a diagram illustrating an energy band structure of the semiconductor layer of the TFET as the p-type transistor.

FIG. 7A is a process diagram illustrating a method of manufacturing the TFET as the method of manufacturing the semiconductor device according to the second embodiment.

FIG. 7B is a process diagram illustrating the method of manufacturing the TFET as the method of manufacturing the semiconductor device according to the second embodiment.

FIG. 7C is a process diagram illustrating the method of manufacturing the TFET as the method of manufacturing the semiconductor device according to the second embodiment.

FIG. 7D is a process diagram illustrating the method of manufacturing the TFET as the method of manufacturing the semiconductor device according to the second embodiment.

FIG. 7E is a process diagram illustrating the method of manufacturing the TFET as the method of manufacturing the semiconductor device according to the second embodiment.

FIG. 7F is a process diagram illustrating the method of manufacturing the TFET as the method of manufacturing the semiconductor device according to the second embodiment.

FIG. 7G is a process diagram illustrating the method of manufacturing the TFET as the method of manufacturing the semiconductor device according to the second embodiment.

FIG. 7H is a process diagram illustrating the method of manufacturing the TFET as the method of manufacturing the semiconductor device according to the second embodiment.

FIG. 7I is a process diagram illustrating the method of manufacturing the TFET as the method of manufacturing the semiconductor device according to the second embodiment.

FIG. 7J is a process diagram illustrating the method of manufacturing the TFET as the method of manufacturing the semiconductor device according to the second embodiment.

FIG. 8A is a process diagram illustrating a modification of the method of manufacturing the TFET.

FIG. 8B is a process diagram illustrating the modification of the method of manufacturing the TFET.

FIG. 8C is a process diagram illustrating the modification of the method of manufacturing the TFET.

FIG. 8D is a process diagram illustrating the modification of the method of manufacturing the TFET.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the TFET disclosed in Patent Document 1 above, the p-type semiconductor layer and the n-type semiconductor layer are made of different materials. Thus, a film forming process is required for each of the p-type semiconductor layer and the n-type semiconductor layer. Further, an isolation etching process is required for each of the p-type semiconductor layer and the n-type semiconductor layer. In addition, when the p-type semiconductor layer and the n-type semiconductor layer are made of different materials, conductive materials including metals that may be ohmic-contacted with the respective p-type and n-type semiconductor layers are often heterogeneous. Thus, a wiring forming process is required for each of the p-type semiconductor layer and the n-type semiconductor layer. Therefore, a method of manufacturing the TFET according to Patent Document 1 has a problem in that the method requires a large number of processes.

To address this issue, in a technology according to the present disclosure, a p-type semiconductor layer and an n-type semiconductor layer are made of a same material, so that the number of processes in a method of manufacturing a semiconductor device is reduced.

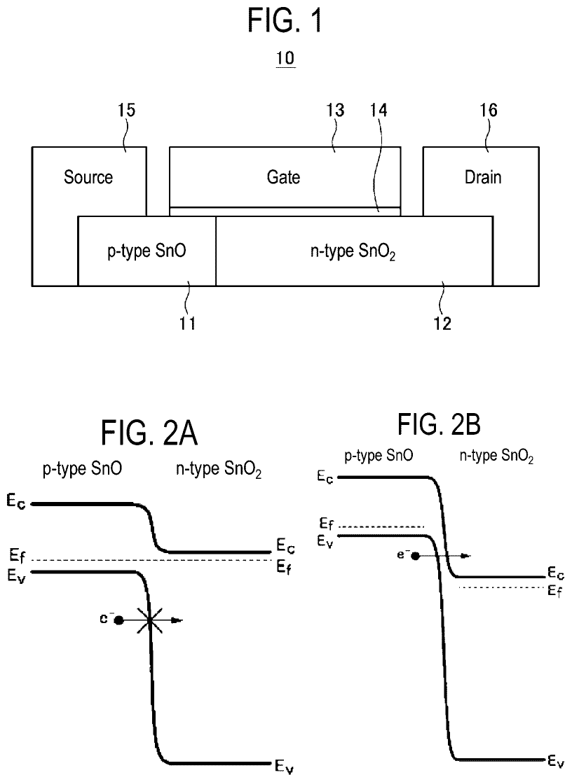

Embodiments of the technology according to the present disclosure are described below with reference to the drawings. First, a first embodiment is described. FIG. 1 is a cross-sectional view schematically illustrating a structure of a TFET manufactured by a method of manufacturing a semiconductor device according to the present embodiment. In FIG. 1, a TFET 10 includes a p-type SnO layer 11 as a p-type tin oxide semiconductor layer and an n-type SnO₂ layer 12 as an n-type tin oxide semiconductor layer. Further, the TFET 10 includes a gate electrode 13, a gate insulating film 14, a source electrode 15, and a drain electrode 16.

In the TFET 10, the p-type SnO layer 11 and the n-type SnO₂ layer 12 are arranged side by side on the same plane to form a semiconductor layer. Further, the source electrode 15 is connected to the p-type SnO layer 11, and the drain electrode 16 is connected to the n-type SnO₂ layer 12. In the TFET 10, the p-type SnO layer 11 and the n-type SnO₂ layer 12 are disposed in a junction between the source electrode 15 and the drain electrode 16. Thus, a pn junction exists between the source electrode 15 and the drain electrode 16. Further, above the p-type SnO layer 11 and the n-type SnO₂ layer 12, the gate electrode 13 is disposed via the gate insulating film 14. Further, in the TFET 10, the source electrode 15 is connected to the p-type SnO layer 11, and therefore, the TFET 10 is an n-type transistor.

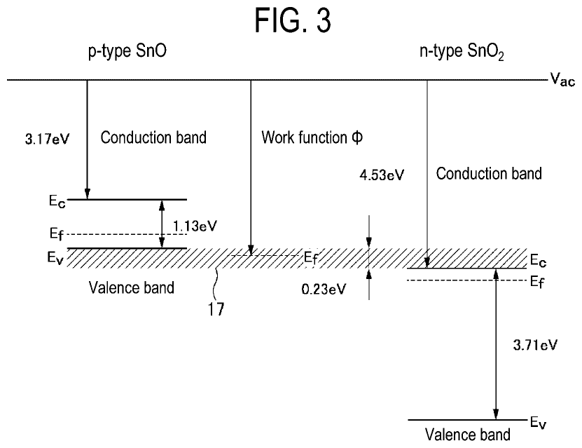

FIGS. 2A and 2B are diagrams illustrating energy band structures of the semiconductor layer of the TFET 10 as the n-type transistor. FIG. 2A shows a case in which no voltage is applied to the gate electrode 13 (transistor off), and FIG. 2B shows a case in which a voltage is applied to the gate electrode 13 (transistor on).

In the case of the transistor off, the p-type SnO layer 11 and the n-type SnO₂ layer 12, which are in a junction, have a coinciding Fermi level E_{f}. However, a valence band (with an upper limit of Eᵥ) of the p-type SnO layer 11 and a conduction band (with a lower limit of E_{c}) of the n-type SnO₂ layer 12 are spaced apart from each other. That is, a barrier exists between the valence band of the p-type SnO layer 11 and the conduction band of the n-type SnO₂ layer 12. Thus, electrons (“e⁻” in the drawing) do not move from the valence band of the p-type SnO layer 11 to the conduction band of the n-type SnO₂ layer 12.

Meanwhile, in the case of the transistor on, the energy band of the p-type SnO layer 11 shifts upwards, and the energy band of the n-type SnO₂ layer 12 shifts downwards. Further, the upper limit Eᵥ of the valence band of the p-type SnO layer 11 exceeds the lower limit E_{c} of the conduction band of the n-type SnO₂ layer 12. Thus, the barrier between the valence band of the p-type SnO layer 11 and the conduction band of the n-type SnO₂ layer 12 is thinned. At this time, electrons behave in a quantum-mechanical manner and pass through the barrier, which may seem like a current flowing through the p-type SnO layer 11 and the n-type SnO₂ layer 12. Such a phenomenon, in which electrons pass through the barrier, is referred to as a tunnel effect. In the TFET 10, switching of current is performed using the tunnel effect.

In addition, in a tin oxide, even in the case of the transistor off, the upper limit Eᵥ of the valence band of the p-type SnO layer 11 and the lower limit E_{c} of the conduction band of the n-type SnO₂ layer 12 are not spaced far apart from each other. Thus, the barrier is easily thinned by the shifts of the energy bands in the case of the transistor on, and the tunnel effect is easily obtained. Therefore, tin oxide is used for the semiconductor layer in the present embodiment.

In addition, by using the tunnel effect, the switching of current may be performed simply by slightly shifting the energy bands of the p-type SnO layer 11 or the n-type SnO₂ layer 12. Hence, using the tunnel effect is advantageous in that only a small voltage needs to be applied to the gate electrode 13.

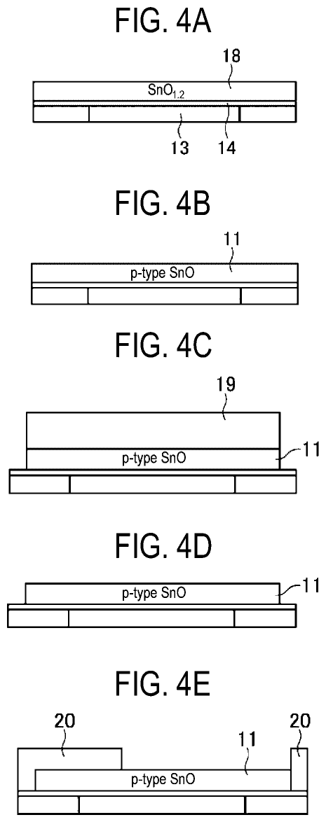

FIG. 3 is a diagram illustrating in detail an energy band structure of the p-type SnO layer 11 and the n-type SnO₂ layer 12 in the case of the transistor on. In the present embodiment, a hole density of the p-type SnO layer 11 is, for example, 9.9×E¹⁷/cm³, and a hole mobility of the p-type SnO layer 11 is, for example, 1.9 cm²/V_{sec}. Further, an electron density of the n-type SnO₂ layer 12 is, for example, 1.6×E¹⁸/cm³, and an electron mobility is of the n-type SnO₂ layer 12, for example, 1.4 cm²/V_{sec}.

At this time, a width of a conduction band of the p-type SnO layer 11 is 3.17 eV, and a bandgap (forbidden band: a difference between the lower limit E_{c} of the conduction band and the upper limit Eᵥ of the valence band) of the p-type SnO layer 11 is 1.13 eV. Further, a width of the conduction band of the n-type SnO₂ layer 12 is 4.53 eV, and a bandgap of the n-type SnO₂ layer 12 is 3.71 eV. Therefore, the upper limit Eᵥ of the valence band of the p-type SnO layer 11 exceeds the lower limit E_{c} of the conduction band of the n-type SnO₂ layer 12, and the valence band of the p-type SnO layer 11 and the conduction band of the n-type SnO₂ layer 12 partially overlap with each other (indicated by hatching in the drawing). A width of the overlapping range (hereinafter, referred to as an “overlapping band”) 17 is 0.23 eV.

Here, a case in which a conductive material including a metal having a work function (a difference between a vacuum level Vac and a Fermi level E_{f}) in the overlapping band 17 is bonded to the p-type SnO layer 11 or the n-type SnO₂ layer 12 is considered. In this case, a Fermi level E_{f} of the conductive material becomes lower than the bandgap of the p-type SnO layer 11. Thus, the Fermi level E_{f} of the conductive material becomes lower than the Fermi level E_{f} of the p-type SnO layer 11. When such a conductive material is bonded to the p-type SnO layer 11, positive holes (holes) do not move from the conductive material to the p-type SnO layer 11, and therefore, acceptors of the p-type SnO layer 11 do not release any holes. Hence, no depletion layer is formed in the p-type SnO layer 11. Accordingly, an ohmic contact is established between the conductive material and the p-type SnO layer 11.

In addition, the Fermi level E_{f} of the conductive material including a metal having a work function Φ in the overlapping band 17 becomes higher than the bandgap of the n-type SnO₂ layer 12. Thus, the Fermi level E_{f} of the conductive material becomes higher than the Fermi level E_{f} of the n-type SnO₂ layer 12. When such a conductive material is bonded to the n-type SnO₂ layer 12, electrons do not move from the conductive material to the n-type SnO₂ layer 12, and therefore, donors of the n-type SnO₂ layer 12 do not release electrons. Hence, no depletion layer is formed in the n-type SnO₂ layer 12, either. Accordingly, an ohmic contact is also established between the conductive material and the n-type SnO₂ layer 12.

That is, by using a conductive material including a metal having a work function Φ in the overlapping band 17 for wiring, it is possible to form a wiring in which ohmic contacts with both the p-type SnO layer 11 and the n-type SnO₂ layer 12 are established, using a conductive material having a same metal.

The overlapping band 17 also refers to a range between a lower limit of the bandgap of the p-type SnO layer 11 and an upper limit of the bandgap of the n-type SnO₂ layer 12. Therefore, a conductive material having a work function in the overlapping band 17 evidently means that the conductive material has a Fermi level lower than the lower limit (conductive band) of the bandgap of the p-type SnO layer 11 and higher than the upper limit (valence band) of the bandgap of the n-type SnO₂ layer 12.

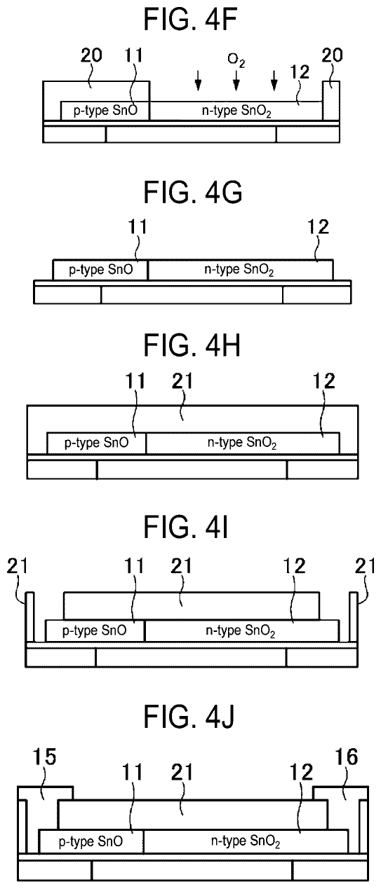

FIGS. 4A to 4J are process diagrams illustrating a method of manufacturing the TFET 10 as the method of manufacturing the semiconductor device according to the present embodiment.

The gate electrode 13 is covered with the gate insulating film 14, and a SnOₓ layer 18 (0.9<x<1.3, the same hereinafter. In the drawing, shown as “SnO_{1.2}” as an example.) is formed so as to face the gate electrode 13 with the gate insulating film 14 interposed therebetween (FIG. 4A). The SnOₓ layer 18 is made of tin oxide of which a ratio of the number of tin atoms to the number of oxygen atoms is 1:x. The SnOₓ layer 18 is formed by alternately sputtering a first target made of metallic tin (Sn) and a second target made of SnO₂ in, for example, a PVD apparatus.

Subsequently, the formed SnOₓ layer 18 is subjected to a thermal processing of, for example, 250 degrees C. to 300 degrees C. in an argon (Ar) atmosphere to crystallize the tin oxide. The SnOₓ layer 18 is oxygen-rich, and therefore, during crystallization, interstitial tin atoms which act as donors are hardly generated. Further, interstitial oxygen atoms and vacancies of tin atoms in the lattice, which act as acceptors, are easily generated. Thus, a conductivity type of the layer becomes a p-type. Accordingly, a p-type SnO layer 11 is formed (FIG. 4B).

Subsequently, the p-type SnO layer 11 is partially covered with a mask 19 made of photoresist or the like, and an isolation etching is performed to remove an excess of the semiconductor layer (FIG. 4C). The mask 19 is then removed (FIG. 4D).

Subsequently, the p-type SnO layer 11 is covered with a mask 20 made of silicon nitride, photoresist, or the like, so as to expose a portion of the remaining p-type SnO layer 11 at a side of the drain electrode 16 (FIG. 4E). An oxidation processing is performed on the exposed p-type SnO layer 11 by subjecting the layer to a thermal processing of, for example, 250 degrees C. to 300 degrees C. in an oxygen (O₂) atmosphere or a nitrous oxide (N₂O) atmosphere. By the oxidation processing of the p-type SnO layer 11, bivalent tin oxide SnO exhibiting a p-type conductivity is changed to tetravalent tin oxide SnO₂. Further, oxygen cavities are easily generated in lattices of SnO₂ and act as donors. Thus, a conductivity type of SnO₂ becomes an n-type. That is, the exposed p-type SnO layer 11 is changed to the n-type SnO₂ layer 12 (FIG. 4F). Therefore, in the present embodiment, a conductivity type of a portion of the p-type SnO layer 11 is changed by the thermal processing (oxidation processing), to form an n-type SnO₂ layer 12. Further, as a portion of the p-type SnO layer 11 is changed to the n-type SnO₂ layer 12, the p-type SnO layer 11 and the n-type SnO₂ layer 12 are joined together to form a pn junction.

Subsequently, the mask 20 is removed (FIG. 4G), and the p-type SnO layer 11 and the n-type SnO₂ layer 12 are covered with a passivation film 21 (FIG. 4H). The passivation film 21 is then partially removed to expose a portion of the p-type SnO layer 11 to form a bonding portion with the source electrode 15, and to expose a portion of the n-type SnO₂ layer 12 to form a bonding portion with the drain electrode 16 (FIG. 4I).

Subsequently, a conductive material including a metal is injected into the portions at which the passivation film 21 is partially removed, and a wiring of the source electrode 15 and a wiring of the drain electrode 16 are formed (FIG. 4J). At this time, a conductive material including a metal having a work function Φ in the overlapping band 17 described above is used for the wirings. By using wirings made of the same conductive material, an ohmic contact is established not only between the source electrode 15 and the p-type SnO layer 11 but also between the drain electrode 16 and the n-type SnO₂ layer 12.

According to the present embodiment, the n-type SnO₂ layer 12 is formed by changing a conductivity type of a portion of the p-type SnO layer 11 by a thermal processing (oxidation processing), and a pn junction is formed in the semiconductor layer of the TFET 10. Thus, in order to form a pn junction, forming a p-type semiconductor layer and an n-type semiconductor layer separately is unnecessary, and the number of film forming processes can be reduced.

In addition, in the isolation etching for removing excess portions of the semiconductor layer, if the p-type semiconductor layer and the n-type semiconductor layer are made of different semiconductors, each of the p-type semiconductor layer and the n-type semiconductor layer requires respective isolation etching.

However, in the present embodiment, before a portion of the p-type SnO layer 11 is changed to the n-type SnO₂ layer 12, not only an excess portion of the p-type SnO layer 11 but also a portion that may become an excess portion of the n-type SnO₂ layer 12 are removed. Thus, only the p-type SnO layer 11 needs to be etched in the isolation etching. Therefore, a plurality of etchings is unnecessary, and the number of isolation etching processes can be reduced.

Further, in the present embodiment, as a conductive material that forms the wiring of the source electrode 15 and the drain electrode 16, a conductive material including the same metal having a work function Φ in the overlapping band 17 is used. By using the same conductive material, wirings in which ohmic contacts with both the p-type SnO layer 11 and the n-type SnO₂ layer 12 are established can be formed. Therefore, simultaneously forming the wirings of the source electrode 15 and the drain electrode 16 is possible, and the number of wiring forming processes can be reduced.

As described above, according to the present embodiment, the number of processes in the method of manufacturing the TFET 10 can be reduced.

In addition, in the method of manufacturing the semiconductor device according to the present embodiment, the temperature of the thermal processing for crystallizing the SnOₓ layer 18 and the temperature of the thermal processing for changing the p-type SnO layer 11 to the n-type SnO₂ layer 12 are relatively low, for example, 250 degrees C. to 300 degrees C., Therefore, in a three-dimensional laminated circuit structure, such as the TFET 10 laminated on a CMOS, for example, preventing a wiring layer of the CMOS from being damaged by high temperature is possible.

In addition, in the TFET 10 manufactured by the method of manufacturing the semiconductor device according to the present embodiment, the pn junction is formed in the semiconductor layer composed of the p-type SnO layer 11 and the n-type SnO₂ layer 12. Therefore, in the case of the transistor off, a current (off-current) flowing in the semiconductor layer can be suppressed. Further, flow of off-current can be suppressed in the case of the transistor off even when a gate length is shortened. This allows the gate length to be shortened, thereby enabling the TFET 10 to be miniaturized.

Next, a second embodiment is described. Configurations and operations of the second embodiment are basically the same as those of the first embodiment described above. Thus, descriptions of redundant configurations and operations are omitted, and configurations and operations, which are different from those of the first embodiment, are described.

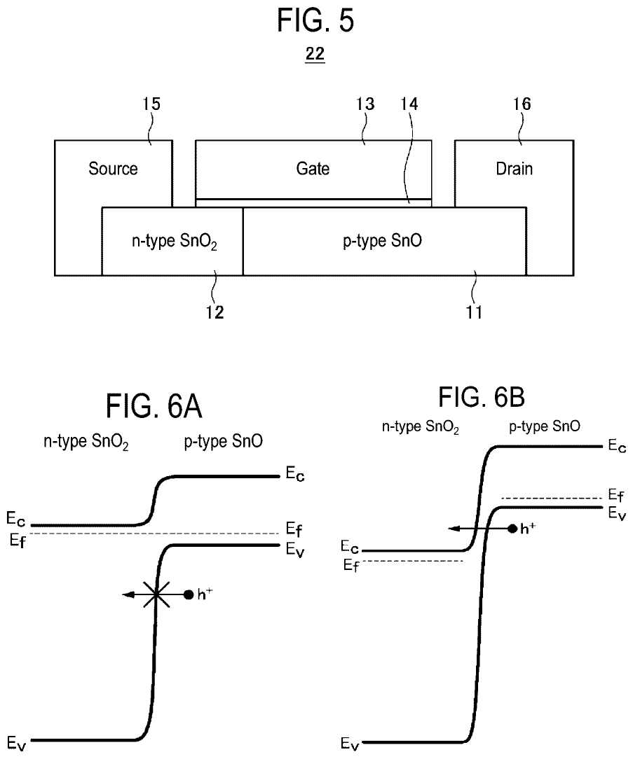

FIG. 5 is a cross-sectional view schematically illustrating a structure of a TFET manufactured by a method of manufacturing a semiconductor device according to the present embodiment. In FIG. 5, in a TFET 22, unlike the TFET 10, the source electrode 15 is connected to the n-type SnO₂ layer 12, and the drain electrode 16 is connected to the p-type SnO layer 11. Meanwhile, the n-type SnO₂ layer 12 and the p-type SnO layer 11 are arranged side by side on the same plane to form a semiconductor layer. That is, in the TFET 22, a pn junction also exists between the source electrode 15 and the drain electrode 16. Further, in the TFET 22, the source electrode 15 is connected to the n-type SnO₂ layer 12, and therefore, the TFET 22 is a p-type transistor.

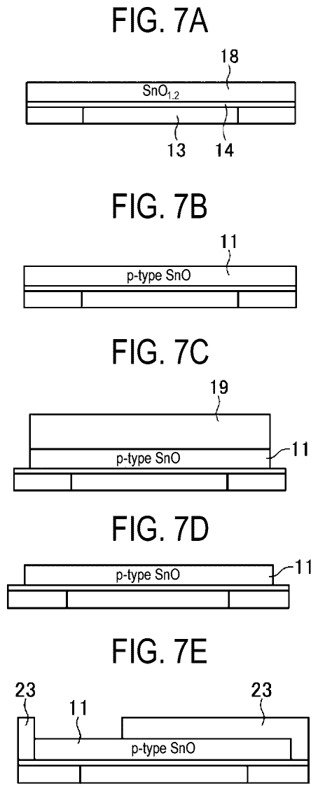

FIGS. 6A and 6B are diagrams illustrating energy band structures of the semiconductor layer of the TFET 22 as the p-type transistor. FIG. 6A shows a case of the transistor off, and FIG. 6B shows a case of the transistor on.

In the case of the transistor off, a barrier exists between the valence band of the p-type SnO layer 11 and the conduction band of the n-type SnO₂ layer 12. Thus, no hole (“h⁺” in the drawing) moves from the valence band of the p-type SnO layer 11 to the conduction band of the n-type SnO₂ layer 12.

Meanwhile, in the case of the transistor on, an energy band of the p-type SnO layer 11 shifts upwards, and an energy band of the n-type SnO₂ layer 12 shifts downwards. Thus, the barrier between the valence band of the p-type SnO layer 11 and the conduction band of the n-type SnO₂ layer 12 is thinned. At this time, holes pass through the barrier by the tunnel effect, which may seem like a current flowing through the p-type SnO layer 11 and the n-type SnO₂ layer 12. In the TFET 22, switching of current is performed using the tunnel effect.

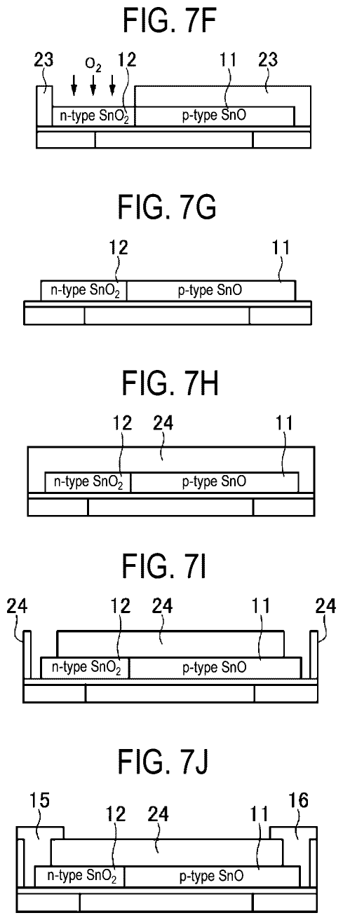

FIGS. 7A to 7J are process diagrams illustrating a method of manufacturing the TFET 22 as the method of manufacturing the semiconductor device according to the present embodiment.

Formation of the SnOₓ layer 18 (FIG. 7A), crystallization of the SnOₓ layer 18 (FIG. 7B), isolation etching of the p-type SnO layer 11 (FIG. 7C), and removal of the mask 19 (FIG. 7D) are sequentially performed. These processes are the same as those shown in FIGS. 4A to 4D, respectively.

Subsequently, the p-type SnO layer 11 is covered with a mask 23 made of silicon nitride, photoresist, or the like, so as to expose a portion of the remaining p-type SnO layer 11 at a side of the source electrode 15 (FIG. 7E). An oxidation processing is performed on the exposed p-type SnO layer 11 by subjecting the layer to a thermal processing of, for example, 250 degrees C. to 300 degrees C. in an oxygen atmosphere or a nitrous oxide atmosphere. At this time, the p-type SnO layer 11 at the side of the source electrode 15 is changed to the n-type SnO₂ layer 12 (FIG. 7F). Further, as a portion of the p-type SnO layer 11 is changed to the n-type SnO₂ layer 12, the p-type SnO layer 11 and the n-type SnO₂ layer 12 are joined together to form a pn junction.

Subsequently, removal of the mask 23 (FIG. 7G), covering with a passivation film 24 (FIG. 7H), and partial removal of the passivation film 24 (FIG. 71) are performed. These processes are the same as those shown in FIGS. 4G to 4I, respectively.

Subsequently, a conductive material including a metal is injected into the portions at which the passivation film 24 is partially removed, and a wiring of the source electrode 15 and a wiring of the drain electrode 16 are formed (FIG. 7J). At this time, the source electrode 15 is connected to the n-type SnO₂ layer 12, and the drain electrode 16 is connected to the p-type SnO layer 11. In the present embodiment, like the first embodiment, a conductive material including a same metal having a work function Φ in the overlapping band 17 described above is used for the wirings. By using wirings made of the same conductive material, an ohmic contact is established not only between the source electrode 15 and the n-type SnO₂ layer 12 but also between the drain electrode 16 and the p-type SnO layer 11.

According to the present embodiment, the n-type SnO₂ layer 12 is formed by changing a conductivity type of a portion of the p-type SnO layer 11 by the thermal processing (oxidation processing), and only the p-type SnO layer 11 is etched in the isolation etching. Further, according to the present embodiment, as a conductive material forming the wirings of the source electrode 15 and the drain electrode 16, the same conductive material having a work function Φ in the overlapping band 17 is used. Thus, like the first embodiment, the present embodiment can also reduce the number of processes in the method of manufacturing the TFET 22.

Needless to say, the present embodiment can achieve the same effects as the first embodiment, such as preventing a wiring layer of a CMOS from being damaged by high temperature, suppressing off-current in the case of the transistor off, and miniaturizing of the TFET 22.

In the above, preferred embodiments of the present disclosure have been described. However, the present disclosure is not limited to the embodiments described above, and various modifications and changes can be made within the spirit and scope of the present disclosure.

In each of the embodiments described above, in the thermal processing for changing the conductivity type of the p-type SnO layer 11, it is possible to easily manufacture the n-type transistor and the p-type transistor distinctively, simply by changing whether the thermal processing is performed at the side of the source electrode 15 or the side of the drain electrode 16. Further, in the manufacturing method of FIGS. 4A to 4J and the manufacturing method of FIGS. 7A to 7J, all the processes are common, except for which one of the side of the source electrode 15 and the side of the drain electrode 16 is to be exposed when covering the p-type SnO layer 11 with the mask 20 or 23. Thus, for example, by using the manufacturing method of FIGS. 4A to 4J and the manufacturing method of FIGS. 7A to 7J in combination, and manufacturing the n-type transistor and the p-type transistor distinctively, two TFETs can be simultaneously manufactured.

In this case, in one TFET, the mask 20 is formed so that a portion of the p-type SnO layer 11 at the side of the drain electrode 16 is exposed, and in the other TFET, the mask 23 is formed so that a portion of the p-type SnO layer 11 at the side of the source electrode 15 is exposed. Accordingly, in the one TFET, the n-type transistor is formed by changing the p-type SnO layer 11 at the drain electrode 16 to the n-type SnO₂ layer 12. Further, in the other TFET, the p-type transistor is formed by changing the p-type SnO layer 11 at the source electrode 15 to the n-type SnO₂ layer 12. Thus, by simultaneously manufacturing the n-type transistor and the p-type transistor, a CMOS structure, which is a complementary circuit configuration including both the n-type transistor and the p-type transistor, is easily formed.

In addition, in each of the embodiment described above, a portion of the p-type SnO layer 11 has been changed to the n-type SnO₂ layer 12. However, a pn junction may be formed in the semiconductor layer by changing a portion of the n-type SnO₂ layer 12 to the p-type SnO layer 11.

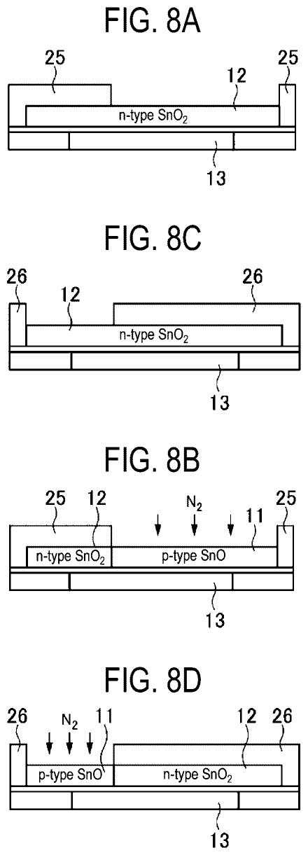

In this case, for example, after forming the n-type SnO₂ layer 12 so as to face the gate electrode 13, isolation etching is performed, and the n-type SnO₂ layer 12 is covered with a mask 25 so that a portion of the remaining n-type SnO₂ layer 12 at the side of the drain electrode 16 is exposed (FIG. 8A). The exposed n-type SnO₂ layer 12 is then subjected to a thermal processing in a nitrogen (N₂) atmosphere. At this time, oxygen cavities in crystal lattices of the tin oxide is replaced by nitrogen atoms to act as acceptors. Accordingly, the n-type SnO₂ layer 12 at the side of the drain electrode 16 is changed to the p-type SnO layer 11 (FIG. 8B). After that, the p-type transistor is manufactured though the same processes as FIGS. 7G to 7J.

In addition, for example, after forming the n-type SnO₂ layer 12 so as to face the gate electrode 13, isolation etching is performed, and the n-type SnO₂ layer 12 is covered with a mask 26 so that a portion of the remaining n-type SnO₂ layer 12 at the side of the source electrode 15 is exposed (FIG. 8C). The exposed n-type SnO₂ layer 12 is then subjected to a thermal processing in a nitrogen atmosphere. Accordingly, the n-type SnO₂ layer 12 at the side of the source electrode 15 is changed to the p-type SnO layer 11 (FIG. 8D). After that, the n-type transistor is manufactured through the same processes as FIGS. 4G to 4J.

That is, even in a case in which a portion of the n-type SnO₂ layer 12 is changed to the p-type SnO layer 11, when simultaneously manufacturing two TFETs, the n-type transistor and the p-type transistor can be simultaneously manufactured by changing a range in which the n-type SnO₂ layer 12 is covered with a mask. Therefore, a CMOS structure which is a complementary circuit configuration including both the n-type transistor and the p-type transistor is easily configured.

According to the technology of the present disclosure, the number of processes in a method of manufacturing a semiconductor device can be reduced.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device including a tin oxide semiconductor having a pn junction between a source electrode and a drain electrode, the method comprising:
changing a conductivity type of a portion of a layer made of the tin oxide semiconductor to form the pn junction.

2. The method of claim 1, wherein the changing of the conductivity type of the portion of the layer made of the tin oxide semiconductor is performed by a thermal processing.

3. The method of claim 2, wherein, in the thermal processing, the tin oxide semiconductor is covered with a mask except for the portion of which the conductivity type is changed.

4. The method of claim 2, wherein a temperature of the thermal processing is 250 degrees C. to 300 degrees C.

5. The method of claim 2, wherein, in the thermal processing, a portion of a p-type tin oxide semiconductor is changed to an n-type tin oxide semiconductor by an oxidation processing.

6. The method of claim 1, wherein a conductive material including a same metal having a Fermi level lower than a lower limit of a bandgap of a p-type tin oxide semiconductor and higher than an upper limit of a bandgap of an n-type tin oxide semiconductor is used for wirings of the source electrode and the drain electrode.

7. The method of claim 1, further comprising:
changing a portion in the layer made of the tin oxide semiconductor where the conductivity type is changed to distinctively manufacture a p-type transistor and an n-type transistor.

8. The method of claim 7, further comprising:
changing portions in a plurality of layers made of the tin oxide semiconductor, where the conductivity types are changed to simultaneously manufacture a p-type transistor and an n-type transistor, and to manufacture a semiconductor device having a complementary circuit configuration including both the n-type transistor and the p-type transistor.

9. The method of claim 1, wherein the semiconductor device is a tunnel field-effect transistor.

10. A semiconductor device manufactured by the method of claim 1.
